(19) United States
(12) Patent Application Publication
(10) Pub. No.: US 2022/0396864 A1
(43) Pub. Date: Dec. 15, 2022

(54) VACUUM PROCESS TREATMENT CHAMBER AND METHOD OF TREATING A SUBSTRATE BY MEANS OF A VACUUM TREATMENT PROCESS

(71) Applicant: EVATEC AG, Trübbach (CH)

(72) Inventor: Jürgen Weichart, Balzers (LI)

(21) Appl. No.: 17/755,159

(22) PCT Filed: Sep. 15, 2020
(86) PCT No.: PCT/EP2020/075763

§ 371 Date: Apr. 22, 2022

(30) Foreign Application Priority Data
Oct. 24, 2019 (CH) 0135619

(51) Int. Cl. C23C 14/00; C23C 14/14

(52) U.S. Cl. CPC C23C 14/0063; C23C 14/14

(57) ABSTRACT

A method for establishing a desired distribution of partial gas pressure along a surface of a substrate when vacuum treating such substrate includes feeding a gas towards the substrate through openings distributed all along the entire periphery of the substrate. The gas is fed or removed at a gas line which communicates exclusively with a set of the openings.

It is known e.g. from the WO 2012/028660, the US2015252475, the US2009013930 to flow a gas into a CVD vacuum process chamber from a shower head type gas distribution arrangement facing the surface of a substrate to be treated.

In the GB2277327 a vacuum process treatment chamber is proposed in which gas is laterally flown towards the surface of a target or of a substrate by means of a gas distribution arrangement which provides for equal flow resistances from a gas inlet to a multitude of gas outlets.

The gas distribution towards the surface of an elongated rectangular sputtering target is performed along the elongated sides of the sputtering target

It is an object of the present invention to propose an alternative vacuum process treatment chamber.

The vacuum process treatment chamber for at least one substrate according to the present invention comprises
A vacuum recipient;
In the vacuum recipient, a substrate support, constructed to support at least one substrate along a substrate plane;
At least one gas-distribution arrangement all-along the periphery of at least one substrate supported on said substrate support.

The gas distribution arrangement comprises at least one first gas line, distant from the periphery, the one or each first gas line being exclusively in gas flow communication with a set of second gas lines, via at least two gas distribution stages and less distant from the periphery, the second gas lines being distributed all along the complete periphery of the substrate.

Each gas distribution stage comprises a stage-specific number of gas distribution spaces.

Each gas distribution space is connected exclusively to one central gas line and to more than one lateral gas lines at respective openings, each lateral gas line at each gas distribution stage is a central gas line at a subsequent of the gas distribution stages.

The first gas line is the central gas line of the gas distribution space of a first gas distribution stage and the second gas lines are the lateral gas lines of the gas distribution spaces of a last gas distribution stage.

The gas flow resistances from the openings of the second gas lines in the gas distribution spaces of the last gas distribution stage to the opening of the respective central gas line in the respective gas distribution spaces, are equal or different.

Nevertheless, the gas flow resistances from the openings of the lateral gas lines in respective gas distribution spaces of the remaining gas distribution stages to the opening of the respective central gas line in the respective gas distribution spaces, are equal.

It has been recognized by the inventor, that even when the vacuum process involves a target, flowing the gas or the gases as exploited by the treatment process homogeneously towards and onto the surface of the substrate to be treated leads to a highly homogeneous distribution of the respective partial pressure all along the addressed surface, under the condition, that the gas flow is established all along the complete periphery of the substrate.

This is especially valid for circular substrates and rectangular substrates at which all sides are of at least similar extent.

If e.g. reactive sputtering is performed from a target the material thereof being electrically more conductive than the material to be deposited on the substrate, then flowing the reactive gas towards the surface of the substrate significantly reduces target poisoning.

The gas flow resistances from the openings of the second gas lines in the gas distribution spaces of the last gas distribution stage to the opening of the respective central gas line in the respective gas distribution spaces, may be different e.g. for treating rectangular substrates with a gas flow established all along the complete periphery of the substrate. In the substrate corners the partial gas pressure may be too high. In such a case the flow resistances to the second gas lines just around the corners are reduced e.g. by pressure stage inserts introduced in the second gas lines.

Further it has to be noted, that it is absolutely possible to combine the gas distribution arrangement according to the present invention with a prior art shower-head gas distribution arrangement e.g. for CVD appliances.

In one embodiment of the vacuum process treatment chamber according to the invention the gas distribution spaces of respective gas distribution stages are equally spaced from the periphery of the substrate.

In one embodiment of the vacuum process treatment chamber according to the invention, at least one of the sets of second gas lines is distributed all along the complete periphery of the substrate.

One embodiment of the vacuum process treatment chamber according to the invention, comprises a number u=2^{k} of second gas lines, wherein k is an integer value of at least 2. Thereby the first gas line may be in flow communication with the u second gas lines via a number 2^{k}−1 of the gas distribution spaces and/or the vacuum process treatment chamber comprises k of the gas distribution stages.

In one embodiment of the vacuum process treatment chamber according to the invention the at least one first gas line is connected or connectable to a gas reservoir.

In one embodiment of the vacuum process treatment chamber according to the invention the at least one first gas line is connected or connectable to a pumping arrangement.

One embodiment of the vacuum process treatment chamber according to the invention comprises more than one of said first gas lines. Thereby at least one of the first gas lines is connected or is connectable to a gas reservoir, another of said first gas lines is connected or connectable to a pumping arrangement and/or one of the first gas lines is connected or connectable to a gas reservoir containing a first gas, another of said first gas lines is connected or connectable to a gas reservoir containing a second gas, different from the first gas.

In embodiments of the vacuum process treatment chamber according to the invention the vacuum process treatment chamber is one of a sputtering chamber, a cathodic arc evaporation chamber, a thermal or electron beam evaporation chamber, an etching chamber, a degasser chamber, a PECVD treatment chamber, a CVD treatment chamber, a PEALD treatment chamber, an ALD treatment chamber.

In one embodiment of the vacuum process treatment chamber according to the invention the vacuum process treatment chamber is a chamber for reactive sputtering and comprises a target of a first material, the at least one first gas line being connected to a gas reservoir containing a reactive gas or gas mixture, reacting with the first material to result in a second material.

In one embodiment of the vacuum process treatment chamber according to the invention the gas distribution stages are staggered in a plane parallel to the substrate plane and/or are staggered in a direction perpendicular to the substrate plane.

In one embodiment of the vacuum process treatment chamber according to the invention the gas distribution stages extend along planes which are parallel to the substrate plane.

In one embodiment of the vacuum process treatment chamber according to the invention the substrate support is constructed to support a circular substrate.

In one embodiment of the vacuum process treatment chamber according to the invention the substrate support is constructed to support a square or rectangular substrate.

In one embodiment of the vacuum process treatment chamber according to the invention, when propagating from the first gas line towards said second gas lines, the spacings between lateral gas lines, considered in planes parallel to the substrate plane, embrace:
At a first gas distribution stage: ½ extent of the periphery of the substrate;
At a further gas distribution stage: ¼ extent of the periphery of the substrate;
At a further gas distribution stage: ⅛ extent of the periphery.

In one embodiment of the vacuum process treatment chamber according to the invention the second gas lines directly abut in a spacing to which the substrate is exposed for vacuum treatment.

In one embodiment of the vacuum process treatment chamber according to the invention the second gas lines abut via a common gas distribution line, looping all-along the periphery, in a spacing to which the substrate is exposed for vacuum treatment.

In one embodiment of the vacuum process treatment chamber according to the invention the substrate support and the gas distribution arrangement are commonly or in mutually synchronized, or independently drivingly movable within the vacuum recipient.

In one embodiment of the vacuum process treatment chamber according to the invention an opposite surface in said vacuum recipient is facing all the surface to be treated of a substrate on the substrate support, and wherein the distances of openings from the second gas lines towards the surface to be treated to the surface to be treated are smaller than the distance from the surface to be treated to the opposite surface.

In one embodiment of the vacuum process treatment chamber according to the invention the openings from the second gas lines towards the surface to be treated of a substrate on the substrate support are distributed along a plane parallel to the substrate plane.

In one embodiment of the vacuum process treatment chamber according to the invention at least the last gas distribution stage is removably mounted to the remainder of said gas distribution stages as an exchange part. Thereby this part acts as a protection shield which may easily be removed, replaced or cleaned in the frame of maintenance. Additionally, such parts with different distributions and/or gas flow resistances of the second gas lines or openings into the space to which the substrate to be treated is exposed, may be selectively mounted.

The invention may be realized with one or more than one embodiment in any combination as long as such embodiments are not contradictory.

The invention is further directed on a method of feeding a gas towards a substrate in a vacuum process treatment chamber or of manufacturing a vacuum process treated substrate, making use of a vacuum process treatment chamber according to the invention or one or more than one of its embodiments.

One variant of the method according to the invention comprises performing by the vacuum process treatment chamber reactive sputtering. Thereby, in one variant, the method comprises sputter depositing on the substrate a material, the electric conductivity thereof being smaller than the electric conductivity of a material of the sputter target.

One variant of the method according to the invention comprises feeding simultaneously and/or consecutively and/or in a time overlapping manner, two or more than two different reactive gases in the reaction space.

Thereby and whenever such reactive gases are simultaneously fed to the reaction space a compound material is deposited. Whenever such reactive gases are fed consecutively thin layers of different materials and including the target material are deposited. Whenever such reactive gases are fed in a time overlapping manner and possibly with time varying gas flow, graded layers are deposited.

The material of the target may be Si. in one variant of the method. In one variant of the method of reactive sputtering according to the invention, at least one of O2 and of N2 is fed to the vacuum process treatment chamber.

The invention shall now be exemplified with the help of figures.

The figures show:

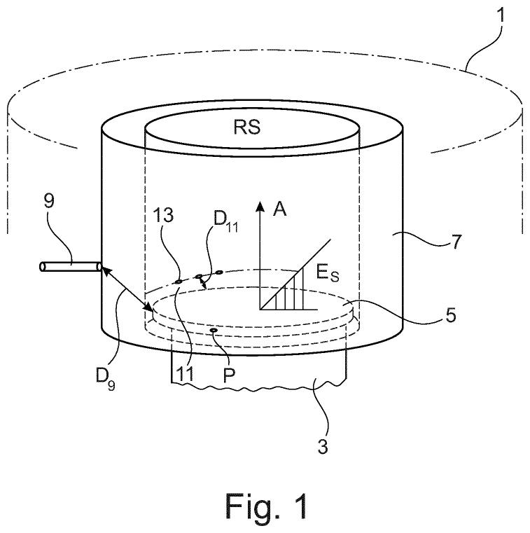

FIG. 1: a simplified and schematic, generic representation of an embodiment of a vacuum process treatment chamber according to the invention for circular substrates;

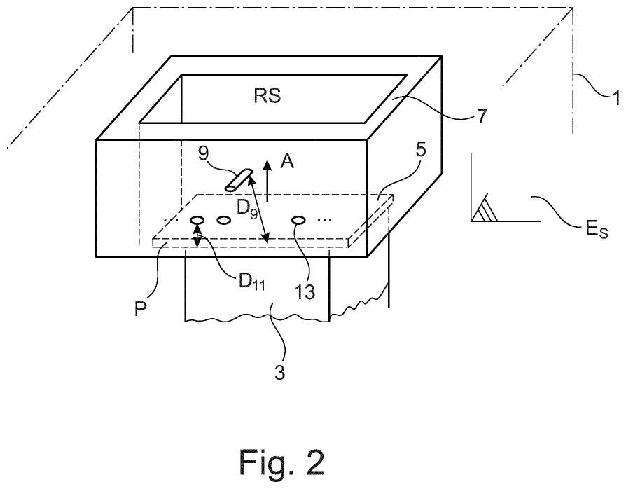

FIG. 2: in a representation in analogy to that of FIG. 1, an embodiment of a vacuum process treatment chamber according to the invention for square or rectangular substrates;

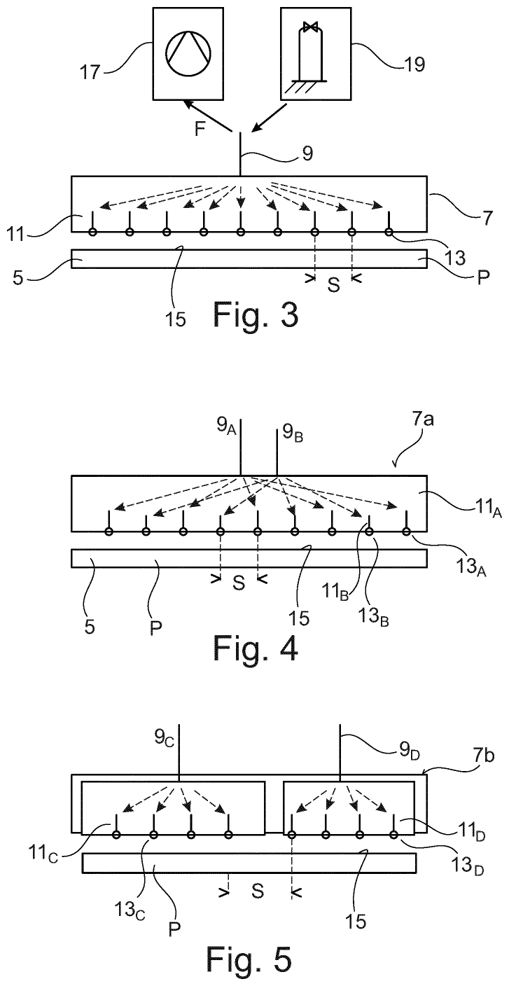

FIG. 3: A schematic and simplified generic and developed representation of an embodiment of a vacuum process treatment chamber according to the invention with single first gas line and set of second gas lines distributed all along the complete periphery of a substrate;

FIG. 4: A schematic and simplified generic and developed representation of an embodiment of a vacuum process treatment chamber according to the invention with double first gas lines and meshed sets of second gas lines distributed all along the complete periphery of a substrate;

FIG. 5: A schematic and simplified generic and developed representation of an embodiment of a vacuum process treatment chamber according to the invention with double first gas lines and unmeshed sets of second gas lines distributed all along the complete periphery of a substrate;

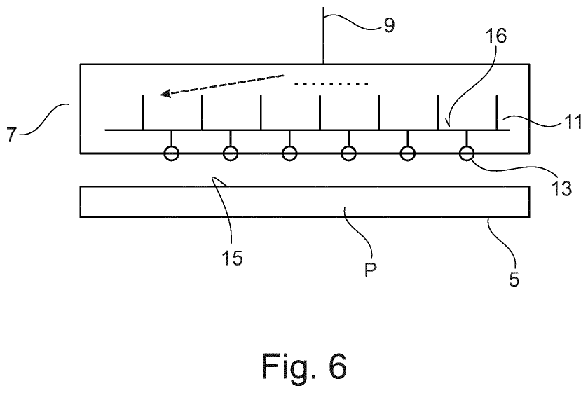

FIG. 6: A schematic and simplified generic and developed representation of an embodiment of a vacuum process treatment chamber according to the invention whereat the second gas lines are interconnected by a common gas line;

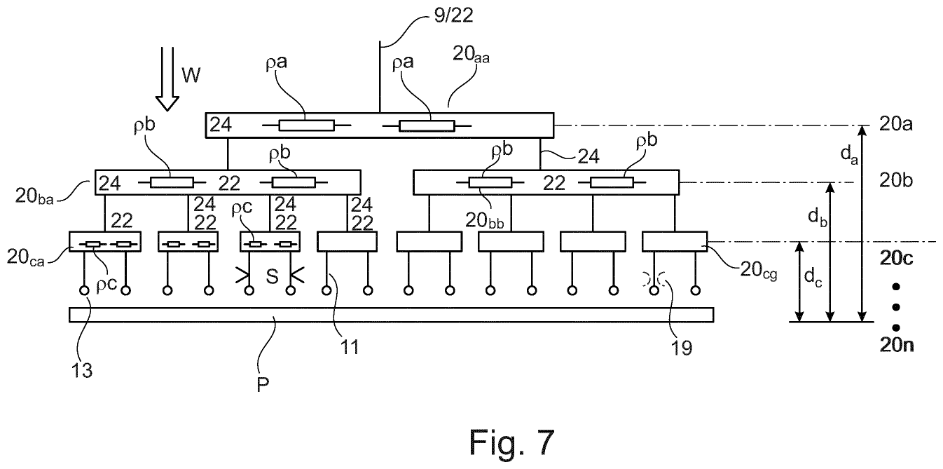

FIG. 7: A schematic and simplified generic and developed representation of an embodiment of a vacuum process treatment chamber according to the invention;

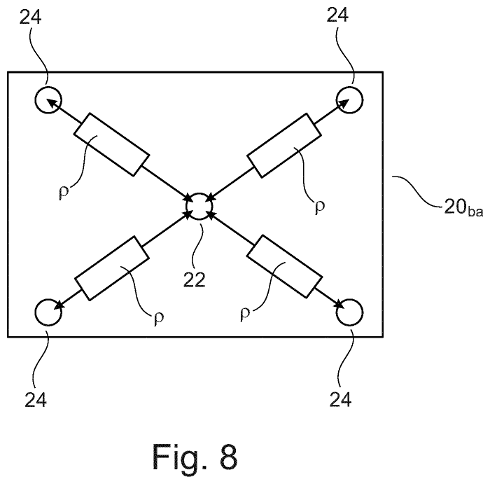

FIG. 8: schematically and simplified, a top view on a two dimensionally extended gas distribution space of an embodiment of a vacuum process treatment chamber according to the invention;

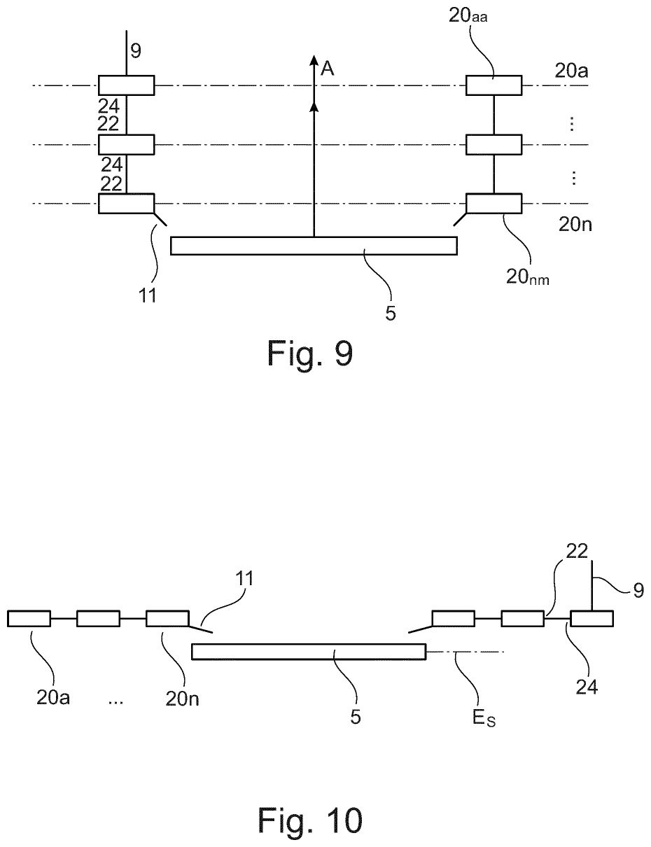

FIG. 9: schematically and simplified a representation of an embodiment of a vacuum process treatment chamber according to the invention whereat the gas distribution stages are staggered in a direction perpendicular to the extended surface of the substrate;

FIG. 10: schematically and simplified a representation of an embodiment of a vacuum process treatment chamber according to the invention whereat the gas distribution stages are staggered in a plane parallel to the extended surface of the substrate;

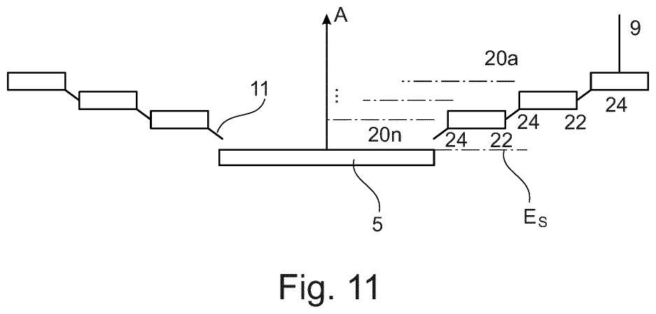

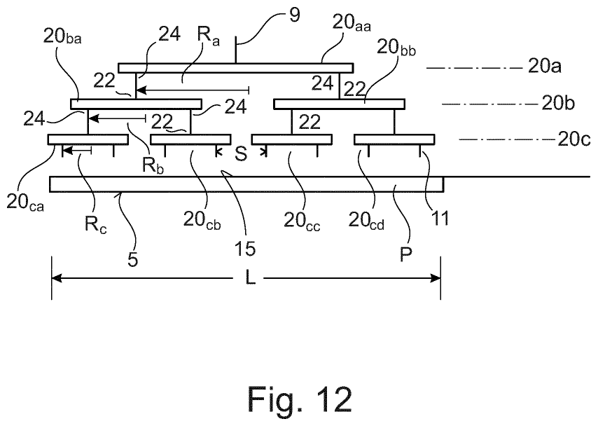

FIG. 11: schematically and simplified a representation of an embodiment of a vacuum process treatment chamber according to the invention whereat the gas distribution stages are staggered in a plane parallel to the extended surface of the substrate and in a direction perpendicular to the extended surface of the substrate; FIG. 12: In a representation in analogy to that of FIG. 7 an embodiment of the vacuum process treatment chamber according to the invention with a 3-fold binary gas line structure;

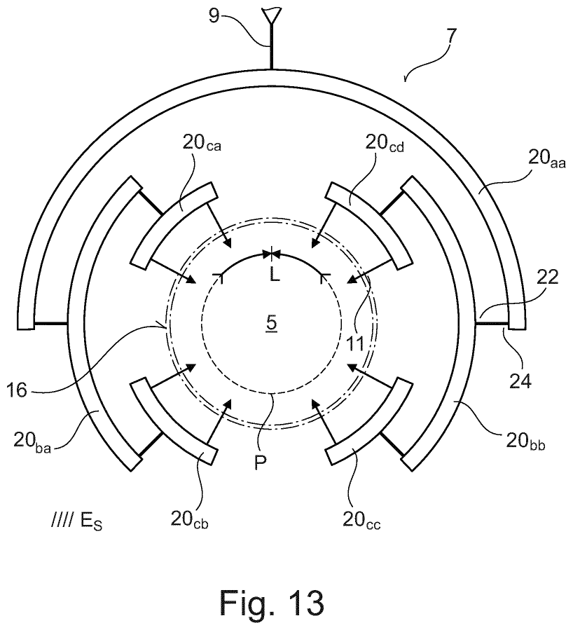

FIG. 13: schematically and simplified the embodiment according to that of FIG. 12 in top view and for circular substrate;

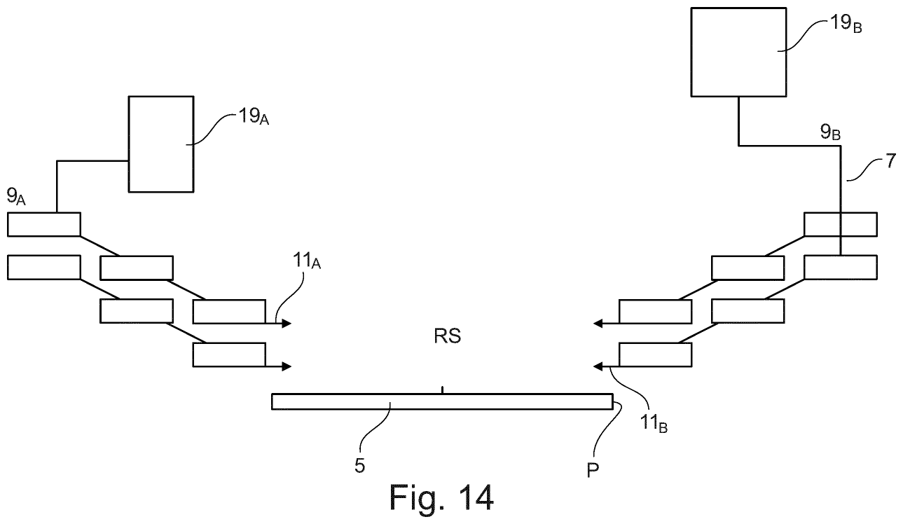

FIG. 14: In a representation in analogy to that of FIG. 12, an embodiment of the vacuum process treatment chamber according to the invention with double first gas lines and sets of second gas lines for feeding different gases, the sets being staggered in a direction perpendicular to the extended surface of the substrate;

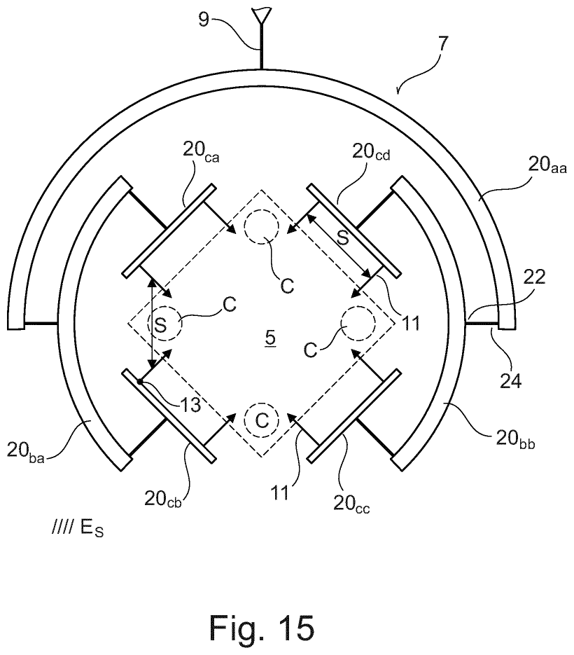

FIG. 15: in a representation in analogy to that of FIG. 13 an embodiment of the vacuum process treatment chamber according to the invention with a 3-fold binary gas line structure for a square or rectangular substrate;

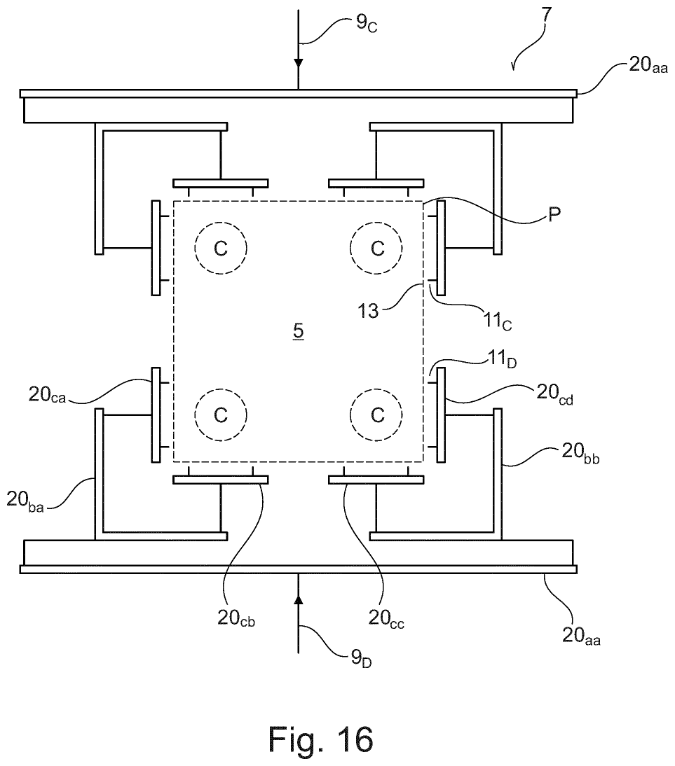

FIG. 16: in a representation in analogy to that of FIG. 13 an embodiment of the vacuum process treatment chamber according to the invention with two 3-fold binary gas line structures arranged according to the embodiment of FIG. 5.

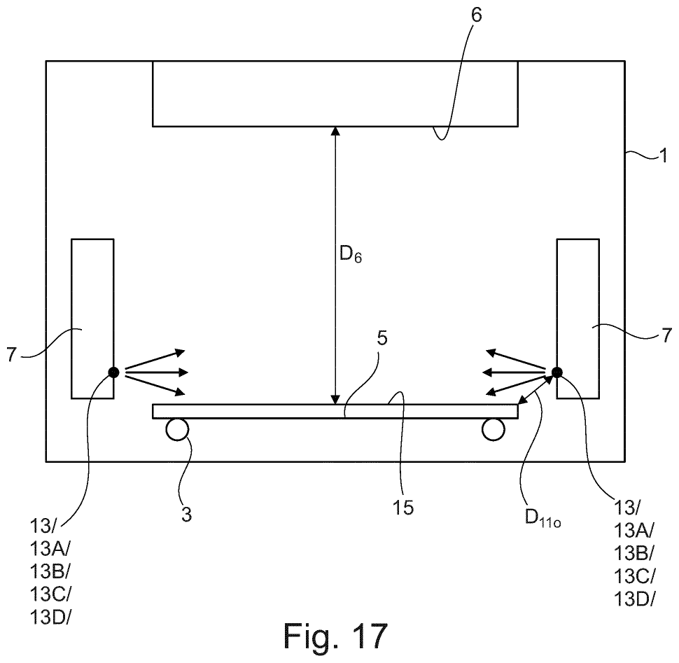

FIG. 17: in a schematic and simplified representation an embodiment of the vacuum process treatment chamber according to the invention, showing the distance relations of openings from the second gas lines towards the extended surface of a substrate and a surface facing and exposed to the extended surface of the substrate and opposite that extended surface.

FIG. 1 and FIG. 2 show, schematically and simplified, the principle of a vacuum process chamber in a perspective view and according to the present invention.

Within a vacuum recipient 1, shown by dash dotted lines, there is provided a substrate support 3 which is constructed to support or hold at least one substrate 5 along a substrate plane Eₛ perpendicular to an axis A. Instead of a single substrate 5 more than one substrate may be supported or held by the substrate support 3 along the plane Eₛ. We also address multiple substrates supported on the substrate support also as “a substrate”.

In the example of FIG. 1 the substrate 5 is circular, in the example according to FIG. 2 the substrate is square or rectangular.

The periphery P of the substrate 5 or the surrounding, common periphery of multiple substrates on the substrate support 3 is all-around completely surrounded by a gas distribution arrangement 7, spaced from the periphery P. This substrate-surrounding gas distribution arrangement 7, structured with respect to gas lines as will be explained later, leaves all the space RS above the substrate 5 free for additional equipment of the vacuum process chamber as also shown in FIG. 17.

The gas distribution arrangement 7 comprises at least one first gas line 9, remote from the periphery 7 by a distance D9. The first gas line 9 is and, whenever more than one first gas lines 9 are provided, each of the first gas lines 9 are , across the gas distribution arrangement 7, exclusively in gas flow communication with a respective set of a number of second gas lines 11 spaced from the periphery P by distances D₁₁ and closer to the periphery than the first gas line 9. As shown in FIG. 17 the openings 13 from the second gas lines 11 into the reaction space RS are closer to the extended surface of the substrate 5 to be treated -D11o- than this extended surface is distant-D6-from a surface 6 opposite to the extended surface of the substrate 5 and facing this extended surface. The opposite surface 6 may e.g. be the surface of a target of a sputtering source.

FIG. 3 shows, schematically and simplified, in a developed view, one example of the gas distribution arrangement 7 according to the invention, extending all along the complete periphery P. Thereby the gas distribution arrangement 7 comprises one single first gas line 9 and one set of a multitude of second gas lines 11 with openings 13 distributed, normally evenly distributed along the periphery P.

The second gas lines 11 of this example directly open at the openings 13 towards the surface 15 of the substrate 5.

In the example of FIG. 4 the gas distribution arrangement 7a comprises more than one first gas line 9, namely e.g. two, 9A and 9B. Each of the first gas lines 9A and 9B is exclusively in flow communication with a respective set of second gas lines 11A and 11B directly opening at openings 13A and 13B towards the surface 15 of the substrate 5.

According to the examples of FIGS. 3 and 4 each set of openings 13, 13A,13B per se is distributed all along the complete periphery P and are thus nested.

In the example of FIG. 5 the gas distribution arrangement 7b comprises more than one first gas lines, 9C and 9D, each exclusively in flow communication with a respective set of second gas lines 11C and 11D, directly opening at respective openings 13C and 13D towards the surface 15 of the substrate 5.

In opposition to the example of FIG. 4, the respective sets of openings 13C and 13D of the example of FIG. 5 embrace each only a part of the extent of periphery P, in combination nevertheless the complete periphery P.

Also in the example of FIG. 5 additional first gas lines 9 (not shown) with respective sets of second gas lines 11 may be provided, e.g. an additional first gas line 9A with the respective set of second gas lines 11A and openings 13A as of the example of FIG. 4 embracing only a part of the extent of periphery P or all along the extent of complete periphery P.

The spacing S between neighboring openings 13,13A,13B.13C,13D may be constant, or the effect of the openings 13 upon the surface 15 of the substrate 5 may be selected, by respectively selecting varying spacings S.

Whereas in the examples of FIGS. 3 to 5 the second gas lines 11,11A,11B,11C and 11D directly open at the respective openings 13,13A,13B,13C,13D towards the surface 15, in other examples as exemplified in FIG. 6 based on the example of FIG. 3, the respective gas lines 11 are interconnected by a common gas line 16, and this common gas line 16 directly communicates with the openings 13. See also the example of FIG. 13.

According to the invention, and according to every example, first gas lines 9,9A,9B 9C,9D are each either connected or connectable to a pumping arrangement 17 or to a gas reservoir 19 as schematically shown in FIG. 3, resulting in a respective gas flow direction F through the gas distribution arrangement 7,7a,7b.

At least one first gas line 9 is connected or connectable to a gas reservoir 19 if the vacuum treatment chamber is e.g.:
A sputtering chamber, whereby e.g. additional first gas lines, connected or connectable to further gas reservoirs may be provided, e.g. to one reservoir for a working gas, to a reservoir for a first reactive gas, to a reservoir for a further, different reactive gas, etc.
A plasma etching chamber, whereby e.g. additional first gas lines, connected or connectable to further gas reservoirs may be provided, e.g. one to a reservoir for a working gas, one to a reservoir for a reactive gas;
A PECVD or a PEALD chamber e.g. for a working gas;
A degasser chamber e.g. for a flushing gas;
A cathodic arc evaporation chamber, whereby additional first gas lines, connected or connectable to further gas reservoirs may be provided, e.g. one to a reservoir for a working gas, one to a reservoir for a reactive gas, one to a reservoir for a further, different reactive gas, etc.
A thermal or electron beam evaporation chamber, e.g. for a reactive gas, whereby e.g. additional first gas lines, connected or connectable to further gas reservoirs may be provided, thus e.g. one to a reservoir for a reactive gas, one to a further reservoir for a further, different reactive gas.

If a first gas line is connected to a reactive gas reservoir e.g. for reactive sputtering, and one or more additional first gas lines are respectively connected to further reactive gas reservoirs for different reactive gases, one may by respective control of the respective gas flows over time realize compound material layer deposition, if the respective reactive gases are fed to the treatment chamber simultaneously, subsequently deposited thin layers of different materials, if the reactive gases are fed to the treatment chamber consecutively or graded layers, if the reactive gases are fed in a time overlapping manner and at respectively controlled flow rates.

At least one first gas line 9 may be connected or connectable to a pumping arrangement 17 if the vacuum treatment chamber is e.g.:
A sputtering chamber e.g. for removing excess working gas and/or reactive gas;
A plasma etching chamber e.g. for removing gaseous etching products;
A PECVD or a PEALD chamber, e.g. for removing excess reactive and/or working gas;
A degasser chamber e.g. for removing degassed products;
A cathodic arc evaporation chamber e.g. for removing excess working and/or reactive gas;
A thermal or electron beam evaporation chamber e.g. for removing excess reactive gas;
An ALD chamber for removing excess gas;
A CVD chamber for removing excess reactive gas.

We will now explain the gas flow interconnection between a first gas line 9 and the second gas lines 11 of the respective set and according to the present invention, by examples which may be applied to all more generic examples of FIGS. 1 to 6.

FIG. 7 shows schematically and simplified an example of such flow interconnection. The first gas line 9 is in flow communication with the second gas lines 11 via a number of gas distribution stages 20, in the example of FIG. 7 via three gas distribution stages 20a, 20b, 20c, generically 20n.

Each gas distribution stage 20n consists of a respective number of gas distribution spaces. In the example of FIG. 7 the gas distribution stage 20a directly communicating with the first gas line 9 consists of one gas distribution space 20aa, more generically 20ax.

The subsequent gas distribution stage 20b consists of two gas distribution spaces 20ba and 20bb, more generically 20by.

The subsequent gas distribution stage 20c consists of eight gas distribution spaces 20ca to 20cg, more generically 20cz.

Thus, even more generically the gas distribution stage 20n has 20nm gas distribution spaces.

Considered in the respective gas distribution stages as of 20n the gas distribution spaces 20nm are equally distant from the periphery P as shown by da, db, dc in the example of FIG. 7. and more generically dm.

Each gas distribution space 20nm exclusively communicates at respective openings with one central gas line 22 and with more than one lateral gas lines 24. Propagating from the first gas line 9 towards the set of second gas lines 11 at the last gas distribution stage, each lateral gas line 24 of one gas distribution stage 20n is the central gas line 22 of a gas distribution space 20(n+1) m at the subsequent gas distribution stage 20n+1.

With an eye on FIG. 7 one can say that the gas distribution spaces downstream the first gas distribution stage are arranged symmetrically to the opening of the first gas line 9 into the first gas distribution space.

The gas distribution spaces downstream the second gas distribution stage are arranged symmetrically to the openings of the central gas lines 22 into the second gas distribution space, etc.

At each gas distribution space, with the exception of at the last gas distribution spaces of the last gas distribution stage which directly opens to the second gas lines 11, the gas flow resistances ρ between the opening of the central gas line 22 and the lateral gas lines 24 are equal. Thus in FIG. 7 all ρa are equal, all ρb are equal but may be different from ρa.

The respective gas flow resistances pc in the gas distribution spaces 20cm which directly communicate with the second gas lines 11 may be equal or may vary. They may be constructed with varying gas flow resistances so as to establish a desired distribution of gas flow or partial pressure along the surface 15 of the substrate 5, additionally or instead of establishing such desired distribution by varying the spacings S.

Respectively e.g. equal flow resistances are reached by respective interconnecting gas lines of equal length and of equal flow cross section. Nevertheless, the gas flow resistances may be adjusted even at equal flow resistance lines, by possibly exchangeable taps with through bores representing desired pressure stages 19 as shown in FIG. 7 with dashed lines.

A gas distribution space with equal flow resistances between the opening of the central gas line 22 and the openings of the lateral gas lines 24 is exemplified in FIG. 8 for one of the gas distributions spaces 20ba,20bb of the example of FIG. 7, which is, as an example, two dimensionally extended. Thereby FIG. 8 shows the gas distribution space e.g. 20ba in view-direction W as shown in FIG. 7. ρ addresses the respective equal gas flow resistances.

Further the gas lines 24-22 interconnecting two neighboring gas distribution stages 20n/20n+1 are equal as well resulting in equal gas flow resistances.

The gas distribution stages may be staggered in direction of the axis A (see FIG. 1) and/or parallel to the plane Eₛ.

FIG. 9 shows schematically and simplified an example in which the gas distribution stages 20a. . . 20n are staggered in direction of the axis A. FIG. 10 shows an example in which the gas distribution stages 20a. . . 20n are staggered parallel to the substrate plane Eₛ and FIG. 11 shows an example in which the gas distribution stages 20a. . . 20n are staggered in direction of axis A and parallel to the substrate plane Eₛ.

The today realized gas line structure between the first gas line 9 and the second gas lines 11 is via a binary tree structure as shown in FIG. 12. Please note that such binary tree structure may be applied in all examples addressed in the FIGS. 1 to 11.

Thereby FIG. 12 is a developed representation and shows, for clearness sake, the gas distribution stages 20a to 20c staggered at least in direction of the axis A.

The first gas line 9 directly communicates as central gas line 22 with the one gas distribution space 20aa of the first gas distribution stage 20a.

The gas distribution space 20aa has two lateral gas lines 24 with openings, equally spaced-Ra-from the opening with which the central gas line 9/22 communicates with the gas distribution space 20aa. The flow resistances between the opening of gas line 9 and each of the openings of the lateral gas lines 24 are equal. The two lateral gas lines 24 embrace ½ of the extent L of the periphery P of the substrate 5 and present equal gas flow resistances.

These two lateral gas lines 24 communicate directly and as a respective central gas line 22 with the two gas distribution spaces 20ba and 20bb of the second gas distribution stage 20b.

Each of the two gas distribution spaces 20ba and 20bb has two lateral gas lines 24, representing equal gas flow resistances, the openings thereof being equally spaced-Rb-from the opening of the respective central gas line 22. The flow resistances between the opening of central gas lines 22 and each of the openings of the lateral gas lines 24 are equal. The mutual spacing of the lateral gas lines 24 of the gas distribution spaces 20ba and 20bb embrace each ¼ of the extent L of the periphery of the substrate 5.

Each of the four lateral gas lines 24 of the two gas distribution spaces 22ba and 20bb communicates directly and as a respective central gas line 22 with one of the four gas distribution spaces 20ca to 20cd of the third gas distribution stage 20c.

Each of the four gas distribution spaces 20ca to 20cd has two lateral gas lines 24, the second gas lines 11. The spacing S and/or the gas flow resistances between the respective openings of the central gas lines 22 and the opening of the respective lateral gas lines 24 in the gas distribution spaces 20ca and 20cb may be varying so as to establish a desired gas distribution along the surface 15 of the substrate 5. The mutual spacings S of all the two lateral gas lines 24 of the gas distribution spaces 20ca to 20cd embraces each ⅛ of the extent L of the periphery of the substrate if such spacing is constant, as realized today.

FIG. 13 shows schematically and simplified a top view of the example according to FIG. 12, and wherein the gas distribution arrangement 7 comprises one single first gas line 9 and embraces the entire length L of the periphery P of a circular substrate 5. For clearness sake the gas distribution stages are shown staggered at least parallel to the substrate plane Eₛ which is parallel to the plane of the drawing. A common gas line 16, in analogy to FIG. 6 which may possibly be provided, is shown in FIG. 13 by dash-dotted lines.

FIG. 14 shows in a representation in analogy to those of FIGS. 9 to 11 an example of the gas distribution arrangement 7 with two first gas lines 9 in analogy to the generic example of FIG. 4, each of the two first gas lines 9A,9B being in gas flow communication with the respective set of second gas lines 11 by a binary line tree as shown in the FIGS. 12 and 13. The first gas lines 9A and 9b are respectively connected or connectable to gas reservoirs 19A and 19B so as to apply to the space RS different gases to be mixed in the space RS or to be applied consecutively or in a overlapping manner over time to the space RS.

Looking back on the example according to the FIGS. 12 and 13 one finds:
a) The number of second gas lines 11 is u=2^{k} wherein k is an integer value of at least 2 and is in the example 3.
b) The first gas line 9 is in flow communication with the u first gas lines via a number 2^{k}−1 of gas distribution spaces 20nm, in the example 7.
c) The first gas line 9 is in flow communication with the u first gas lines via a number k of gas distribution stages 20n, in the example 3.

The gas introduction comprises e.g. according to FIG. 12:
A single point gas injection, by a first gas line 9;
The single point gas injection is connected via a first gas distribution space 20aa and two lateral gas transition points, at the lateral gas lines 24, in the positions: 90° and 270° to two second level gas distribution spaces 20ba and 20bb. The first distribution space 20aa is a partial annulus or circle and covers an angle of >180°
The second level distribution spaces 20ba and 20bb form partial annuli and cover an angle of >90° and provide in total four gas transition points at their lateral gas lines 24 in the positions: 45° , 135° , 225° and 315° to four third level gas distribution spaces 20ca to 20cd.
optional third level gas distribution spaces form partial annuli, cover an angle of >45° and provide in total eight gas transition points, at respective lateral gas lines, in the positions: 22.5°+n*45°(n=0 . . . 7)
optional fourth level gas distribution space form partial annuli and cover an angle of >22.5° and provide in total 16 gas transition points, at respective lateral gas lines, in the positions: 11.25°+n*22.5°(n=0 . . . 15)

FIG. 15 shows the example of FIGS. 12 and 13 applied to a square shaped substrate 5.

FIG. 16 shows an example in which the gas distribution arrangement 7 comprises two first gas lines 9C and 9D in analogy to the more generic example of FIG. 5, applied to a square shaped substrate 5, each of the two first gas lines 9C,9D being in gas flow communication with the respective set of second gas lines 11C,11D by a binary line tree as shown in the FIGS. 12 and 13. The openings 13 are distributed along the complete periphery of the substrate 5.

It is to be noted that e.g. in the examples of FIG. 15 and FIG. 16 a varying spacing S may be advantageous e.g. to cope with effects at the corner areas C of the substrate 5.

On the other hand and as shown in the corner areas C of the square substrate 5 in the FIG. 15 or 16 e.g. due to constructional requirements and spacing S of subsequent openings 13, the partial gas pressure in these areas C may become higher than along remaining parts of the extended surface 15 of the substrate 5 .In such case, the gas flow resistances of the respective second gas lines 11 may be reduced, e.g. by pressure stages introduced in these lines. Such pressure stages may be realized by inserts or taps flexibly applicable and exchangeable in the respective second gas lines 11.

If (not shown in the drawings) the substrate 5 is linearly movable or is rotated around an axis which is parallel to but spaced from the central axis A of the substrate 5, the gas distribution arrangement 7 may be moved together with the substrate 5. If the substrate 5 is merely rotated around the central axis A then the gas distribution arrangement 7 may or may not be rotated as well about the addressed axis A thereby in synchronism with the rotation of the substrate 5 or establishing a desired relative rotation between the substrate 5 and the gas distribution arrangement 7.

The overall gas distribution arrangement or at least the innermost gas distribution stage with the respective gas distribution spaces, may be constructed as an exchange part, easily dismountable and mountable to the more exterior parts of the gas distribution arrangement, which significantly simplifies cleaning maintenance.

The vacuum treatment chamber according to the invention may especially be used where more than one reactive gas is to be applied towards the substrate. If these gases are premixed, then the gas distribution arrangement necessitates only one gas line connected or connectable to a gas reservoir with the premixed gas. If e.g. the mixture of such gases is to be varied during the vacuum treatment process, then these gases may be supplied in a controlled manner via more than one first gas lines.

Today the vacuum treatment chamber according to the invention is a reactive sputtering chamber.

Two reactive gases O2 and N2 are premixed and fed via a single first gas line towards the surface of a substrate. A Si target is sputtered and a SiNxOy layer is deposited on the substrate.

In another process reactive gases O2 and N2 are premixed and fed via a single first gas line towards the surface of a substrate. A Ti target is sputtered and a TiOxNy layer is deposited on the substrate.

Feeding the reactive gases, especially O2 to the surface of the substrate rather than to the target surface, significantly prevents target poisoning.

What is claimed is:

1. A vacuum process treatment chamber for at least one substrate comprising:
A vacuum recipient;
In said vacuum recipient, a substrate support (3), constructed to support at least one substrate (5) along a substrate plane (Eₛ);
At least one gas-distribution arrangement (7) all-along the periphery (P) of at least one substrate supported on said substrate support;
Said gas distribution arrangement (7) comprising at least one first gas line (9), distant (D₉) from said periphery, the or each first gas line being exclusively in gas flow communication with a set of second gas lines (11) via at least two gas distribution stages (20a,20b,20c) and less distant (D₁₁) from said periphery, said second gas lines being distributed all along the complete periphery;
each gas distribution stage comprising a stage-specific number of gas distribution spaces (20aa,20ba,20bb,20ca to 20 cg);
Each gas distribution space (20aa,20ba,20bb,20ca to 20 cg) being connected exclusively to one central gas line(22) and to more than one lateral gas lines(24) by respective openings, each lateral gas line(24) at each gas distribution stage(20a,20b,20c) being a central gas line (22) at a subsequent of said gas distribution stages (20a to 20c), whereby
The first gas line (9) being the central gas line of the gas distribution space of a first gas distribution stage;
The second gas lines (11) being the lateral gas lines of the gas distribution spaces of a last gas distribution stage;
the gas flow resistances from the openings of the second gas lines (11) in the gas distribution spaces of the last gas distribution stage to the opening of the respective central gas line (22) in the respective gas distribution spaces, being equal or different whereby
the gas flow resistances from the openings of the lateral gas lines (24) in respective gas distribution spaces of the remaining gas distribution stages to the opening of the central gas line (22) in the respective gas distribution spaces, being equal.

2. The vacuum process treatment chamber of claim 1 wherein the gas distribution spaces of respective gas distribution stages are equally spaced from said periphery.

3. The vacuum process treatment chamber of claim 1 wherein at least one of said sets of second gas lines is distributed all along the complete periphery.

4. The vacuum process treatment chamber of claim 1 comprising a number u=2^{k} of said second gas lines, wherein k is an integer value of at least 2.

5. The vacuum process treatment chamber of claim 3 said first gas line being in flow communication with said u second gas lines via a number 2^{k} −1 of said gas distribution spaces.

6. The vacuum process treatment chamber of claim 4 comprising k of said gas distribution stages.

7. The vacuum process treatment chamber of claim 1 wherein said at least one first gas line is connected or connectable to a gas reservoir.

8. The vacuum process treatment chamber of claim 1 wherein said at least one first gas line is connected or connectable to a pumping arrangement.

9. The vacuum process treatment chamber of claim 1 comprising more than one of said first gas lines.

10. The vacuum process treatment chamber of claim 9 one of said first gas lines being connected or connectable to a gas reservoir, another of said first gas lines being connected or connectable to a pumping arrangement.

11. The vacuum process treatment chamber of claim 9 one of said first gas lines being connected or connectable to a gas reservoir containing a first gas, another of said first gas lines being connected or connectable to a gas reservoir containing a second gas, different from said first gas.

12. The vacuum process treatment chamber of claim 1 wherein said chamber is one of a sputtering chamber, a cathodic arc evaporation chamber, a thermal or electron beam evaporation chamber, an etching chamber, a degasser chamber, a PECVD treatment chamber, a CVD treatment chamber, a PEALD treatment chamber, an ALD treatment chamber.

13. The vacuum process treatment chamber of claim 1 being a chamber for reactive sputtering and comprising a target of a first material, said at least one first gas line being connected to a gas reservoir containing a reactive gas or gas mixture, reacting with said first material to result in a second material.

14. The vacuum process treatment chamber of claim 1 wherein said gas distribution stages are staggered in a plane parallel to the substrate plane and/or are staggered in a direction perpendicular to said substrate plane.

15. The vacuum process treatment chamber of claim 1 wherein said gas distribution stages extend along planes parallel to said substrate plane.

16. The vacuum process treatment chamber of claim 1 wherein said substrate support is constructed to support a circular substrate.

17. The vacuum process treatment chamber of claim 1 wherein said substrate support is constructed to support a square or rectangular substrate.

18. The vacuum process treatment chamber of claim 1 wherein, propagating from said first gas line towards said second gas lines, the spacings between lateral gas lines, considered in planes parallel to the substrate plane, embrace:
At a first gas distribution stage: ½ extent of the periphery of the substrate;
At a further gas distribution stage: ¼ extent of the periphery of the substrate;
At a further gas distribution stage: ⅛ extent of said periphery.

19. The vacuum process treatment chamber of claim 1 wherein said second gas lines directly abut in a spacing to which said substrate is exposed for vacuum treatment.

20. The vacuum process treatment chamber of claim 1 wherein said second gas lines abut via a common gas distribution line, looping all-along said periphery, in a spacing to which said substrate is exposed for vacuum treatment.

21. The vacuum process treatment chamber of claim 1 wherein said substrate support and said gas distribution arrangement are commonly or mutually synchronized or independently drivingly movable within said vacuum recipient.

22. The vacuum process treatment chamber of claim 1 wherein an opposite surface in said vacuum recipient is facing all the surface to be treated of a substrate on said substrate support, and wherein the distances of openings from said second gas lines towards said surface to be treated to said surface to be treated are smaller than the distance from said surface to be treated to said opposite surface.

23. The vacuum process treatment chamber of claim 1 wherein openings from said second gas lines towards said surface to be treated of a substrate on said substrate support are distributed along a plane parallel to said substrate plane.

24. The vacuum process treatment chamber of claim 1 wherein at least said last gas distribution stage is removably mounted to the remainder of said gas distribution stages as an exchange part.

25. A method of feeding a gas towards a substrate in a vacuum process treatment chamber or of manufacturing a vacuum process treated substrate, making use of vacuum process treatment chamber according to claim 1.

26. The method of claim 25, comprising performing by said vacuum process treatment chamber reactive sputtering.

27. The method of claim 26, comprising sputter depositing on the substrate a material, the electric conductivity thereof being smaller than the electric conductivity of a material of the sputter target.

28. The method of claim 26 comprising feeding simultaneously and/or consecutively and/or in a time overlapping manner, two or more than two different reactive gases in the reaction space.

29. The method of claim 26, wherein said material of the sputter target is Si.

30. The method of claim 24 wherein at least one of O2 and of N2 is fed to said vacuum process treatment chamber.
